(19) United States
(12) Patent Application Publication
(10) Pub. No.: US 2001/0018237 A1
(43) Pub. Date: Aug. 30, 2001

(54) Method for fabricating a nonvolatile dram memory cell

(76) Inventors: Walter Hartner, Munchen (DE); Marcus Kastner, Ottobrunn (DE); Gunther Schindler, Munchen (DE)

Correspondence Address: LERNER AND GREENBERG, P.A., Post Office Box 2480, Hollywood, FL, 33022-2480, US

(21) Appl. No.: 09/761,807

(22) Filed: Jan. 16, 2001

(30) Foreign Application Priority Data
Jan. 13, 2000 (DE) 100 01 118.7

(51) Int. Cl. H01L 21/335

(52) U.S. Cl. 438/142

(57) ABSTRACT

When fabricating a DRAM memory cell with a switching transistor and a storage capacitor containing a ferroelectric dielectric and platinum electrodes, a conductive protective layer is applied to the upper electrode at least in the region of a contact opening formed in an insulation layer, so that tungsten can be filled into the contact opening with a chemical vapor deposition in an H₂ atmosphere without the dielectric being reduced by the hydrogen under the catalytic action of the platinum. A semiconductor component is also provided.

### BACKGROUND OF THE INVENTION

Field of the Invention

The invention relates to a semiconductor component and to a method for fabricating a semiconductor component. In particular, the invention relates to a method for fabricating a nonvolatile memory cell with a switching transistor and a storage capacitor. The capacitor plates of the storage capacitor contain a platinum metal or a conductive oxide of a platinum metal. A metal-oxide-containing layer, in particular a ferroelectric or paraelectric layer, is provided as a dielectric layer between the capacitor plates.

Conventional microelectronic semiconductor memory components (DRAMs) essentially include a selection or switching transistor and a storage capacitor in which a dielectric material is fitted between two capacitor plates. The dielectric materials are usually oxide layers or nitride layers which have a dielectric constant of at most approximately 8. To reduce the size of the storage capacitor and to produce nonvolatile memories, new types of capacitor materials (ferroelectrics or paraelectrics) with considerably higher dielectric constants are required. A few of these materials are listed in the publication “Neue Dielektrika fur Gbit-Speicherchips” [New dielectrics for Gbit memory chips] by W. Hönlein, Phys. Bl. 55 (1999). To fabricate ferroelectric capacitors for use in nonvolatile semiconductor memory components with a high integration density, it is possible, for example, to use ferroelectric materials, such as strontium bismuth tantalate (SBT), strontium bismuth tantalate niobate (SBTN) such as SrBi₂(Ta,Nb)₂O₉, lead zirconate titanate (PZT) such as Pb(Zr,Ti)O₃ or barium titanate (BTO) such as Bi₄Ti₃O₁₂ as a dielectric between the capacitor plates. However, it is also possible to use a paraelectric material, such as barium strontium titanate (BST) (Ba,Sr)TiO_{3.}

However, the use of these new types of dielectrics, ferroelectrics or paraelectrics places new demands on the semiconductor process technology. Firstly, these new types of materials can no longer be combined with the traditional electrode material, namely polycrystalline silicon. Therefore, it is necessary to use inert electrode materials, such as for example platinum metals or their conductive oxides (e.g. RuO₂). The reason for this is that after the deposition of the ferroelectric, the latter has to be annealed or heat-treated (conditioned), possibly a number of times, in an oxygen-containing atmosphere at temperatures of approximately 550-800° C. Therefore, to avoid undesirable chemical reactions between the ferroelectric and the electrodes, the latter are generally produced from platinum or another sufficiently temperature-stable and inert material, such as another platinum metal (Pd, Ir, Rh, Ru, Os).

When constructing a DRAM (dynamic random access memory) cell, there are substantially two different structural concepts, which have the common feature that the switching transistor is formed in a lower plane directly on the semiconductor substrate and the storage capacitor is provided in an upper plane, the two being separated from one another by an intervening insulation layer.

According to the first structural concept (“stacked cell”), the switching transistor and the storage capacitor are provided substantially directly above one another, the lower electrode of the storage capacitor and the drain region of the MOS transistor being electrically connected to one another by a contact hole which is filled with a conductive material (“plug”) and passes through the insulation layer.

According to the second structural concept (“offset cell”), the switching transistor and the storage capacitor are provided offset from one another, the upper electrode of the storage capacitor being electrically connected to the drain region of the MOS transistor through two contact holes.

To simplify the illustration, in FIG. 1 both structural concepts of a conventional DRAM memory cell are shown combined in a single component. In the text which follows, the component structure is initially explained in more detail with reference to the stacked cell.

First of all, a MOS transistor 2 is fabricated on a semiconductor component 1 as a result of a drain region 21 and a source region 23 being formed by doping, between which regions there is a channel, the conductivity of which can be controlled by a gate 22 provided above the channel. The gate 22 may be formed by or connected to a word line WL of the memory component. The source region 23 is connected to a bit line BL of the memory component. The MOS transistor 2 is then covered with a planarizing insulation layer 4, usually including an oxide such as SiO₂. A storage capacitor 3 is formed on this insulation layer 4 as a result of firstly a lower electrode 31 being applied and patterned, which lower electrode is electrically connected to the drain region 21 of the MOS transistor 2 through a contact hole 41 which is filled with a conductive material, such as polycrystalline silicon. Then, a dielectric layer 32 of a ferroelectric or paraelectric material is deposited, for example by MOCVD (Metal Organic Chemical Vapor Deposition), on the lower electrode 31, which layer forms the capacitor dielectric. In the lateral direction, this layer 32 extends beyond the lower electrode 31, forming a step, and an upper electrode 33 is deposited on the entire surface of this layer. This lateral side region of the dielectric layer 32 and the upper electrode 33 contributes to the memory capacity. Finally, the structure obtained is in turn covered by a second planarizing insulation layer 5, for example an oxide layer, such as SiO₂. A further contact hole 51 is formed in this layer, through which contact hole the upper electrode 33 of the storage capacitor 3 can be connected to an outer electrical connection P (common capacitor plate) through the use of a suitable conductive material. The source region 23 of the MOS transistor 2 is connected to the bit line BL as a result of a contact hole 45, which extends through both insulation layers 4 and 5, being formed and filled with a conductive material.

In the offset cell structure, the same type of contact hole 46 extending through both insulation layers 4 and 5 is formed in order to connect the drain region 24 of the MOS transistor to the upper electrode of the storage capacitor through the use of a conductive interconnection 8 and a further contact hole 52, which extends through the insulation layer 5.

Therefore, with both memory cell types it is necessary for the upper electrode 33 of the storage capacitor 3 to be connected to an outer electrical connection by the conductive material with which a contact hole has been filled. Since it is known that tungsten (W), in particular in the case of small structure sizes, is eminently suitable for filling contact holes of this type in a CVD process, a tungsten CVD process is used as standard for high storage densities. However, since the deposition of tungsten using the CVD (chemical vapor deposition) process takes place in an H₂-containing atmosphere and the platinum has the property of acting as a catalyst, the reduction of BiOₓ causes damage to the ferroelectric material SBT of the dielectric layer 32 situated beneath the upper platinum electrode. For the other possible materials for the dielectric layer 32 mentioned above, there are similar damage mechanisms caused by hydrogen and the catalytic action of the platinum or the platinum metal used in each case. This damage at least partially ruins the success which is to be achieved with the novel dielectric materials.

### SUMMARY OF THE INVENTION

It is accordingly an object of the invention to provide a DRAM memory cell and a method for fabricating a semiconductor component which overcome the above-mentioned disadvantages of the heretofore-known methods and components of this general type and which provide a DRAM memory cell in which a ferroelectric or paraelectric layer of a capacitor dielectric, which is applied during a process sequence, is substantially not impaired by further process steps.

In particular, it is an object of the invention to provide a method for fabricating a DRAM memory cell in which the upper electrode, which is produced from a platinum metal, of the storage capacitor is connected to an outer electrical connection by a contact hole, which is to be filled with tungsten and which passes through an insulation layer, in such a manner that the dielectric layer which lies below the upper electrode is substantially not impaired.

With the foregoing and other objects in view there is provided, in accordance with a first embodiment of the invention, a method for fabricating a semiconductor component, the method includes the steps of:

forming a switching transistor on a semiconductor substrate;

applying a first insulation layer on the switching transistor;

forming a storage capacitor on the first insulation layer such that the storage capacitor is coupled to the switching transistor, the storage capacitor including a lower electrode, an upper electrode and a metal-oxide-containing layer disposed between the lower electrode and the upper electrode, the lower electrode and the upper electrode containing a material selected from the group consisting of a platinum metal and a conductive oxide of a platinum metal;

applying a second insulation layer on the storage capacitor;

forming a contact opening in the second insulation layer for providing an electrical contact between the upper electrode and an outer contact connection;

subsequently applying, in the contact opening, a conductive protective layer on the upper electrode; and

subsequently filling the contact opening with tungsten by using a chemical vapor deposition in a hydrogen atmosphere.

According to another mode of the first embodiment of the invention, the lower electrode and the upper electrode are formed from platinum or from a material containing platinum.

According to yet another mode of the first embodiment of the invention, the metal-oxide containing layer is formed as a dielectric layer including a ferroelectric material such as a strontium bismuth tantalate compound, a strontium bismuth tantalate niobate compound, for example SrBi₂(Ta,Nb)₂O₉, a lead zirconate titanate compound, for example Pb(Zr,Ti)O₃, or a barium titanate compound, for example Bi₄Ti₃O₁₂.

According to another mode of the first embodiment of the invention, the metal-oxide containing layer is formed as a dielectric layer including a paraelectric material such as a barium strontium titanate compound, for example (Ba,Sr)TiO_{3.}

According to yet another mode of the first embodiment of the invention, the conductive protective layer is formed from a high-temperature superconductor, for example YBa₂Cu₃O₇, a nitride, for example WN or TaN, a carbide, for example WC, or from WSi, IrOₓ, RhOₓ, RuOₓ, OsOₓ, SrRuO₃, LaSrCoO_{x.}

According to a further mode of the first embodiment of the invention, subsequent to the step of forming the contact opening, the conductive protective layer is applied as a first covering layer substantially entirely covering the semiconductor substrate; a tungsten layer is applied as a second covering layer substantially entirely covering the semiconductor substrate; and material of the conductive protective layer and of the tungsten layer is removed in a region outside the contact opening by chemical mechanical polishing.

According to another mode of the first embodiment of the invention, after the step of applying the first insulation layer, a first contact hole is formed in the first insulation layer. Via the first contact hole, a first contact is provided between a drain region of the switching transistor and the lower electrode. after the step of applying the second insulation layer, a second contact hole which passes through the first and second insulation layers is formed. Via the second contact hole, a second contact between a source region of the switching transistor and a further outer contact connection is provided.

According to another mode of the first embodiment of the invention, after the step of applying the second insulation layer, a first contact hole which passes through the second insulation layer and the first insulation layer is formed. Via the first contact hole, a first contact between a source region of the switching transistor and an outer contact connection is provided. After the step of applying the second insulation layer, a second contact hole is formed which passes through the second insulation layer and the first insulation layer. Via the second contact hole, a second contact is provided between the drain region and a further outer contact connection. After the step of applying the second insulation layer, a third contact hole is formed which passes through the second insulation layer. Via the third contact hole, a third contact is provided between the upper electrode and the further outer contact connection.

With the objects of the invention in view there is also provided, in accordance with a second embodiment of the invention, a method for fabricating a semiconductor component, the method includes the steps of:

forming a switching transistor on a semiconductor substrate;

applying a first insulation layer on the switching transistor;

forming a storage capacitor on the first insulation layer such that the storage capacitor is coupled to the switching transistor, the storage capacitor including a lower electrode, an upper electrode and a metal-oxide-containing layer disposed between the lower electrode and the upper electrode, the lower electrode and the upper electrode containing a material selected from the group consisting of a platinum metal and a conductive oxide of a platinum metal;

applying a conductive protective layer at least in a given region of the upper electrode;

subsequently applying a second insulation layer on the storage capacitor;

forming, at the given region of the upper electrode, a contact opening in the second insulation layer for providing an electrical contact between the upper electrode and an outer contact connection;

after the steps of applying the second insulation layer and forming the contact opening, filling the contact opening with tungsten by using a chemical vapor deposition in a hydrogen atmosphere.

According to another mode of the second embodiment of the invention, the lower electrode and the upper electrode are formed from platinum or from a material containing platinum.

According to yet another mode of the second embodiment of the invention, the metal-oxide containing layer is formed as a dielectric layer including a ferroelectric material such as a strontium bismuth tantalate compound, a strontium bismuth tantalate niobate compound, for example SrBi₂(Ta,Nb)₂O₉, a lead zirconate titanate compound, for example Pb(Zr,Ti)O₃, or a barium titanate compound, for example Bi₄Ti₃O_{12.}

According to another mode of the second embodiment of the invention, the metal-oxide containing layer is formed as a dielectric layer including a paraelectric material such as a barium strontium titanate compound, for example (Ba,Sr)TiO₃.

According to yet another mode of the second embodiment of the invention, the conductive protective layer is formed from a high-temperature superconductor, for example YBa₂Cu₃O₇, a nitride, for example WN or TaN, a carbide, for example WC, or from WSi, IrOₓ, RhOₓ, RuOₓ, OsOₓ, SrRuO₃, LaSrCoO_{x.}

According to yet another mode of the second embodiment of the invention, the conductive protective layer is formed from a temperature resistant material which can withstand temperatures of over 650° C. in an O₂ atmosphere, in particular WSi, IrOₓ, RhOₓ, RuOₓ, OsOₓ, SrRuO₃, LaSrCoOₓ, and a high-temperature superconductor, for example YBa₂Cu₃O_{7.}

According to a further mode of the second embodiment of the invention, the upper electrode is formed by applying an electrode layer substantially entirely over the semiconductor substrate. Subsequently the conductive protective layer is applied on the electrode layer such that the protective layer substantially entirely covers the electrode layer. The electrode layer and the conductive protective layer are pattered by using photolithography and etching.

According to yet a further mode of the second embodiment of the invention, after the step of applying the first insulation layer, a first contact hole is formed in the first insulation layer. Via the first contact hole, a first contact is provided between a drain region of the switching transistor and the lower electrode. After the step of applying the second insulation layer, a second contact hole is formed which passes through the first and second insulation layers. Via the second contact hole, a second contact is provided between a source region of the switching transistor and a further outer contact connection.

According to another mode of the second embodiment of the invention, after the step of applying the second insulation layer, a first contact hole is formed which passes through the second insulation layer and the first insulation layer. Via the first contact hole, a first contact between a source region of the switching transistor and an outer contact connection is provided. After the step of applying the second insulation layer, a second contact hole is formed which passes through the second insulation layer and the first insulation layer. Via the second contact hole, a second contact is provided between a drain region and a further outer contact connection. After the step of applying the second insulation layer, a third contact hole is formed which passes through the second insulation layer. Via the third contact hole, a third contact is provided between the upper electrode and the further outer contact connection.

A common feature of both embodiments of the invention is that the upper electrode of the storage capacitor, at least in the region of the contact hole, which may not yet have been formed, of the second insulation layer, is covered with a protective layer, which substantially prevents the possibility of a reaction between hydrogen and the material of the dielectric layer, catalyzed by the platinum metal, taking place at the interface between the upper electrode and the dielectric layer.

In the first embodiment of the invention, a switching transistor is formed on a semiconductor substrate, a first insulation layer is applied to the switching transistor, then a storage capacitor, which is coupled to the switching transistor and contains a lower electrode and an upper electrode and a metal-oxide-containing layer which has been deposited between the electrodes, is applied to the first insulation layer, a second insulation layer is applied to the storage capacitor, in which second insulation layer a contact opening for making electrical contact between the upper electrode and an outer contact connection is formed, a conductive protective layer being applied to the upper electrode after the second insulation layer has been applied and the contact hole has been formed in the second insulation layer, and then the contact hole being filled with tungsten by chemical vapor deposition (CVD) under a hydrogen atmosphere.

According to the second embodiment of the invention, even before the second insulation layer is applied, the conductive protective layer is applied to substantially the entire surface of the upper electrode and is preferably patterned together with the upper electrode layer through the use of photolithography and etching. After the second insulation layer has been applied and the contact hole has been formed, the latter is then filled with tungsten by chemical vapor deposition (CVD) under a hydrogen atmosphere. Since post-annealing has to be carried out after the patterning of the upper electrode layer and the conductive protective layer, in this embodiment only materials which are able to withstand relatively high temperatures of for example 650° C. in an O₂ atmosphere can be used for the conductive protective layer. Suitable materials include, for example, WSi, IrOₓ, RhOₓ, RuOₓ, OsOₓ, SrRuO₃, LaSrCoOₓ (LSCO), or a HT (high temperature) superconductor (YBa₂Cu₃O₇, . . . )

By contrast, in the first embodiment it is also possible to use materials which are not able to withstand high temperatures in an O₂ atmosphere, since in this case the conductive protective layer is applied only after the patterning and post-annealing of the upper electrode layer. Therefore, in addition to the materials listed above, it is also possible, for example, to use nitrides (WN, TaN, . . . ) or carbides (WC, . . . ).

In the first embodiment, it is possible, after the contact opening has been formed, to initially apply the protective layer to the entire surface, in which case the contact opening is lined with the protective layer. Then, tungsten is applied to the structure through the use of CVD, so that the contact opening is filled up with tungsten. Next, the protective layer and the tungsten layer outside the contact opening are removed by chemical mechanical polishing (CMP), so that the second insulation layer outside the contact opening is exposed again.

To ensure that the tungsten material grows on the protective layer in the contact opening, a nucleation layer, for example of titanium or titanium nitride or a Ti/TiN double layer, has to be applied before the deposition of the conductive protective layer on the upper electrode layer. On account of the very high affinity of titanium for oxygen, the Ti is oxidized by diffusion on account of its proximity to the conductive protective layer (e.g. IrOₓ). Therefore, it is advantageous to use the following layer combinations: Pt/IrOₓ/Ir/Ti/TiN/W or Pt/Ir/Ti/TiN/W or Pt/IrOₓ/TiN/W.

With the objects of the invention in view there is also provided, a semiconductor component, including:

a semiconductor substrate;

a switching transistor formed on the semiconductor substrate;

a first insulation layer disposed on the switching transistor;

a storage capacitor formed on the first insulation layer, the storage capacitor being coupled to the switching transistor and including a lower electrode, an upper electrode and a metal-oxide-containing layer disposed between the lower electrode and the upper electrode;

the lower and upper electrodes of the storage capacitor containing a material selected from the group consisting of a platinum metal and a conductive platinum metal oxide;

a second insulation layer disposed on the storage capacitor;

the second insulation layer being formed with a contact opening and tungsten filling the contact opening;

a conductive protective layer disposed in the contact opening and at least on the upper electrode; and

an outer contact connection electrically contacting the upper electrode.

According to another feature of the invention, the conductive protective layer in the contact opening is disposed only on the upper electrode.

According to another feature of the invention, the second insulation layer defines inner walls for the contact opening; and the conductive protective layer covers the inner walls.

According to yet another feature of the invention, the lower and upper electrodes contain or consist of platinum.

According to a further feature of the invention, the metal-oxide-containing layer is a dielectric layer including a ferroelectric material, such as SrBi₂ (Ta, Nb) ₂O₉, Pb (Zr, Ti)O₃, and Bi₄Ti₃O_{12 .}

According to another feature of the invention, the metal-oxide-containing layer is a dielectric layer including a paraelectric material, in particular (Ba,Sr)TiO_{3.}

According to yet another feature of the invention, the conductive protective layer is formed of a high-temperature superconductor, for example YBa₂Cu₃O₇, a nitride, for example WN or TaN, a carbide, for example WC, or from WSi, IrOₓ, RhOₓ, RuOₓ, OsOₓ, SrRuO₃ or LaSrCoO_{x.}

According to another feature of the invention, the first insulation layer is formed with a first contact hole; the switching transistor has a drain region and a source region; a first conductive material fills the first contact hole for providing a contact between the drain region and the lower electrode; the first and second insulation layers are formed with a second contact hole which passes through the first and second insulation layers; a second conductive material fills the second contact hole; and a further outer contact connection contacts the source region via the second conductive material.

According to yet a further feature of the invention, the first and second insulation layers are formed with a first contact hole which passes through the first and second insulation layers; the switching transistor has a drain region and a source region; a first conductive material fills the first contact hole; a further outer contact connection is contacted to the source region via the first conductive material; the first and second insulation layers are formed with a second contact hole which passes through the first and second insulation layers; a second conductive material is disposed in the second contact hole; another outer contact connection contacts the drain region via the second conductive material; the second insulation layer is formed with a third contact hole which passes through the second insulation layer; and a third conductive material is disposed in the third contact hole for providing a contact between the another outer contact connection and the upper electrode.

Other features which are considered as characteristic for the invention are set forth in the appended claims.

Although the invention is illustrated and described herein as embodied in a method for fabricating a nonvolatile DRAM memory cell, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, cross-sectional view of a conventional DRAM memory cell in the two memory configurations;

FIG. 2A-2C are diagrammatic, cross-sectional views of a DRAM memory cell according to the invention, after individual method steps according to the first embodiment of the method of the invention; and

FIG. 3 is a diagrammatic, cross-sectional view of a DRAM memory cell which has been completed in accordance with the second embodiment of the method according to the invention.

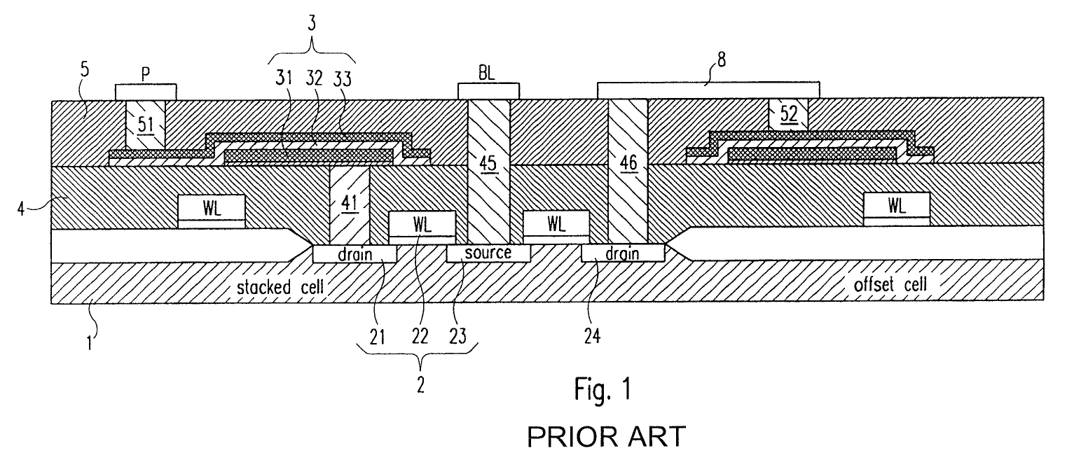

### DESCRIPTION OF THE PREFERRED EMBODIMENTS

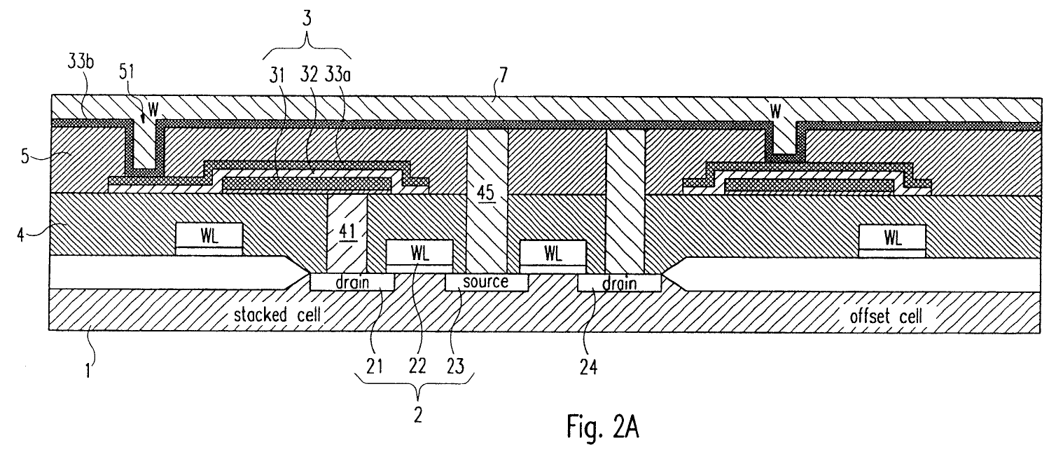

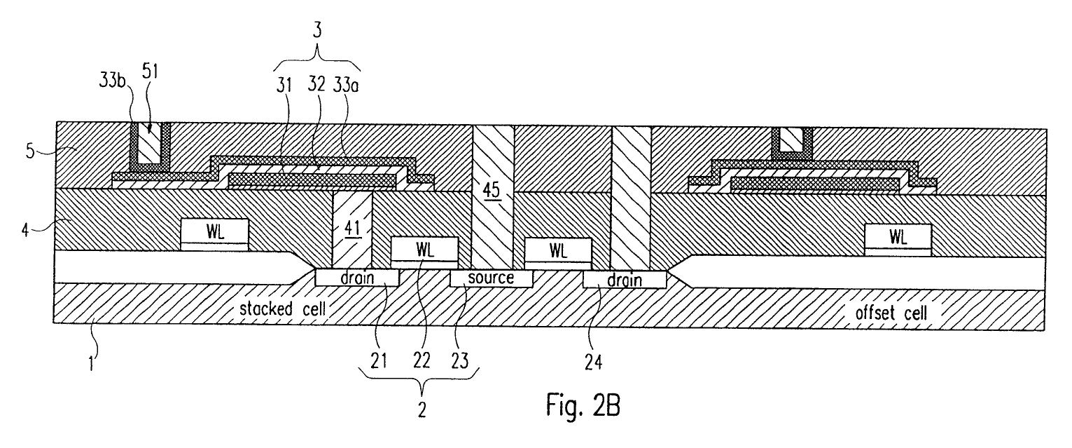

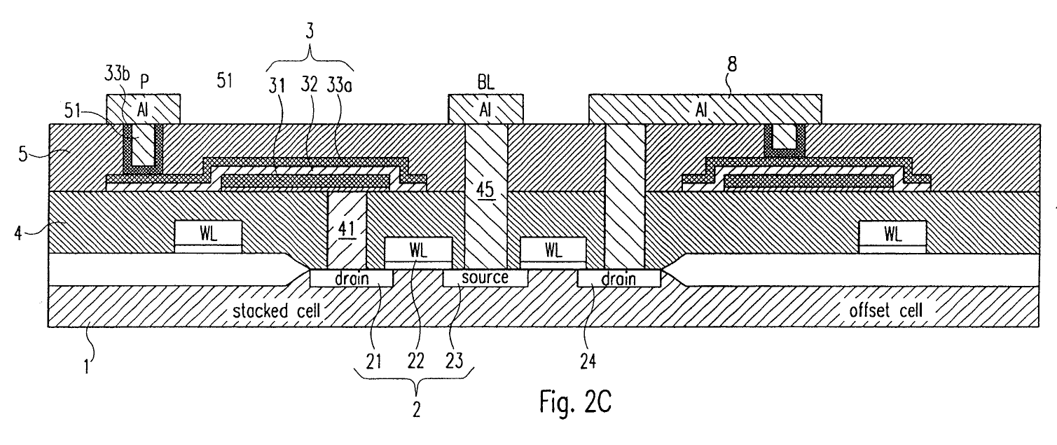

Referring now to the figures of the drawings in detail and first, particularly, to FIGS. 2A-2C thereof, there are illustrated individual method steps of the first embodiment of the invention using cross-sectional views of the corresponding intermediate products involved in the fabrication of the DRAM memory cell. In these figures, in each case both a stacked cell memory component and an offset cell memory component are shown formed on a common semiconductor substrate 1, the two memory components being illustrated with a common source region 23. This is done purely for reasons of simplifying the illustration of the two component configurations within one figure. The invention is essentially explained on the basis of the stacked cell memory component and reference numerals are only used for the stacked cell configuration in the figures. However, the following explanations apply in a similar way to the offset cell memory component.

First of all, a MOS transistor 2 is formed in the semiconductor substrate 1 (e.g. Si) in a manner known per se by forming drain and source regions 21 and 23 and a gate 22 which controls the channel between drain and source through the use of a voltage which is present across the word line WL. The transistor structure is then planarized by deposition of an insulation layer 4, for example an oxide layer such as SiO₂. A contact hole 41 is formed in this insulation layer 4 and is filled with a conductive material, such as polycrystalline silicon or tungsten, in a CVD process. Then, a storage capacitor 3 is formed on the insulation layer 4. In this process, initially a lower electrode 31 is applied above the contact hole 41, which lower electrode forms one of the storage plates of the storage capacitor 3 and is connected to the drain region 21 of the switching transistor 2 through the contact hole 41. Then, a dielectric layer 32 is deposited on the lower electrode 31, which dielectric layer is formed by a metal-oxide-containing material, preferably by a ferroelectric or a paraelectric. The ferroelectric material used may, for example, be SrBi₂(Ta,Nb)₂O₉ (SBT or SBTN), Pb(Zr,Ti)O₃ (PZT) or Bi₄Ti₃O₁₂ (BTO). The paraelectric material used may, for example, be (Ba,Sr)TiO₃ (BST). Then, an upper electrode 33a is deposited on the dielectric layer 32 and is then patterned together with the dielectric layer 32 by photolithography and etching. The deposition and patterning of the dielectric layer 32 and the upper electrode 33a is preferably carried out in such a manner that both layers, at least on one side of the lower electrode 31, extend beyond the latter in the lateral direction and bear against the lower electrode 31 in the form of a step.

Then, a second planarizing insulation layer 5, for example an oxide layer such as SiO₂, is applied to the storage capacitor 3. A continuous contact hole 45 is formed in this second insulation layer and the first insulation layer 4 lying beneath it, and is filled with a conductive material, such as tungsten or polycrystalline silicon, in order to electrically connect the source region 23 to an external connection.

Then, a contact opening 51, which extends as far as the upper electrode 33a of the storage capacitor 3, is etched into the second insulation layer 5. In the stacked cell, this contact opening 51 is formed in the edge region of the upper electrode 33a, while in the offset cell it is formed in a central region of the upper electrode 33a.

Then, a conductive protective layer 33b, which according to the invention is used to prevent the hydrogen which is present during the subsequent CVD tungsten deposition from damaging the dielectric layer 32 during the CVD process, is applied to the entire surface of the structure produced in this way. The material used for the conductive layer 33b may, for example, be IrOₓ or WSi. However, in the present embodiment other materials, such as for example nitrides (WN, TaN, . . . ) or carbides (WC, . . . ), are theoretically also suitable. In any event, the action of the conductive protective layer 33b must be such that the maximum possible barrier action with respect to hydrogen passing through is achieved and/or the maximum possible reduction of the catalytic, i.e. hydrogen-dissociating, action of the platinum is brought about on its surface. Both possibilities allow to suppress damage to the material of the dielectric layer 32 at the opposite interface between the upper electrode 33a and the dielectric layer 32.

After deposition of the conductive protective layer 33b, which lines the contact opening 51, firstly a nucleation layer, which allows the tungsten material to grow on in the following step, is applied to the protective layer 33b in the region of the contact opening 51. The nucleation layer used may, for example, be a layer of Ti or TiN or a double layer formed from the two materials. Then, tungsten is deposited on the entire structure by CVD, so that finally a tungsten layer 7 which covers the entire structure in planar form has been deposited. This CVD may, as is conventional, be carried out under a H₂ atmosphere, since the conductive protective layer 33b now forms sufficient protection against damage to the dielectric layer 32.

In a subsequent method step, the protective layer 33b and tungsten layer 7 which have been applied outside the contact opening 51 are abraded again by chemical mechanical polishing (CMP), so that the second insulation layer 5 is exposed on the outside again in the regions outside the contact opening 51. The result of this method step is illustrated in FIG. 2B.

Finally, FIG. 2C shows how, in the final method step, interconnects P and BL (bit line) are applied to the contact lead-throughs. In addition, in the offset cell structure, a conductive connection 8 from the drain contact lead-through to the contact lead-through of the upper electrode is applied. The interconnects and connections are usually produced from aluminum.

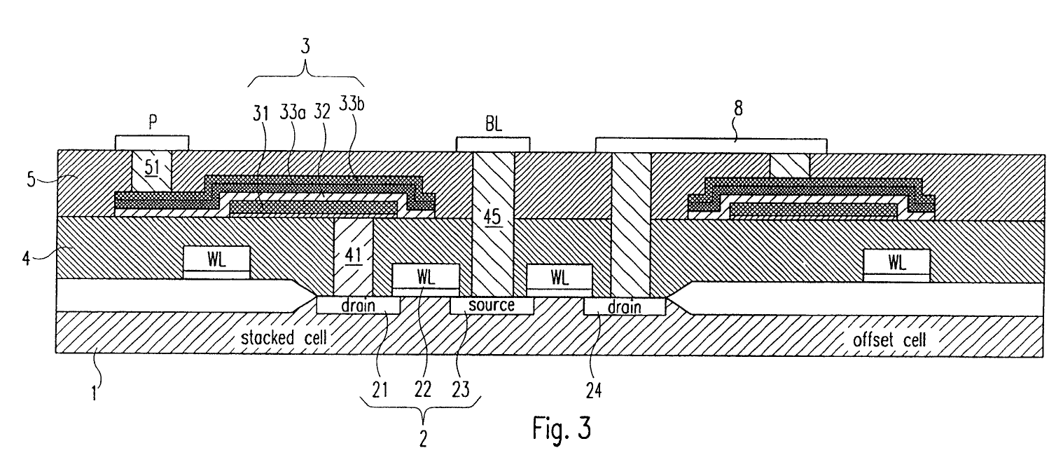

A second embodiment of the invention is explained with reference to FIG. 3. In this case, the conductive protective layer 33b is applied to the upper electrode 33a immediately after the deposition of the latter and both layers together are patterned by photolithography and etching to the size and form desired for the upper electrode 33a. Then, the planarizing insulation layer 5 is applied to the structure obtained and the contact opening 51 is formed in the insulation layer 5 down to the conductive protective layer 33b and filled with tungsten in a subsequent CVD step.

In this embodiment, the material used for the protective layer 33b must be able to withstand the relatively high temperature in an O₂ atmosphere, since after the forming and patterning of the layers 33a and 33b, at least when platinum is used for the layer 33a, a post-anneal has to be carried out under the conditions described. Therefore, suitable conductive materials for the protective layer 33b are, in addition to WSi, the oxides IrOₓ, RhOₓ, RuOₓ, OsOₓ, SrRuO₃, LaSrCoOₓ (LSCO, lanthanum strontium cobalt oxide), or a high-temperature superconductor (YBa₂Cu₃O₇, . . . ).

As an alternative, after the upper electrode layer 33a has been deposited, it is possible firstly to carry out an annealing step at a relatively high temperature, for example 600-800° C., and then the protective layer 33b can be deposited on the upper electrode layer 33a, after which an annealing step at a relatively low temperature, for example 500° C., can be carried out. The result is the same structure as in FIG. 3. However, since the protective layer 33b is only exposed to a relatively low temperature during the second annealing step, it can be used for a greater number of materials.

We claim:

1. A method for fabricating a semiconductor component, the method which comprises:
forming a switching transistor on a semiconductor substrate;
applying a first insulation layer on the switching transistor;
forming a storage capacitor on the first insulation layer such that the storage capacitor is coupled to the switching transistor, the storage capacitor including a lower electrode, an upper electrode and a metal-oxide-containing layer disposed between the lower electrode and the upper electrode, the lower electrode and the upper electrode containing a material selected from the group consisting of a platinum metal and a conductive oxide of a platinum metal;
applying a second insulation layer on the storage capacitor;
forming a contact opening in the second insulation layer for providing an electrical contact between the upper electrode and an outer contact connection;
subsequently applying, in the contact opening, a conductive protective layer on the upper electrode; and
subsequently filling the contact opening with tungsten by using a chemical vapor deposition in a hydrogen atmosphere.

2. The method according to claim 1, which comprises forming the lower electrode and the upper electrode from a material containing platinum.

3. The method according to claim 1, which comprises forming the lower electrode and the upper electrode from platinum.

4. The method according to claim 1, which comprises forming the metal-oxide containing layer as a dielectric layer including a ferroelectric material.

5. The method according to claim 1, which comprises forming the metal-oxide containing layer as a dielectric layer including a ferroelectric material selected from the group consisting of a strontium bismuth tantalate compound, a strontium bismuth tantalate niobate compound, a lead zirconate titanate compound and a barium titanate compound.

6. The method according to claim 1, which comprises forming the metal-oxide containing layer as a dielectric layer including a ferroelectric material selected from the group consisting of SrBi₂(Ta,Nb)₂O₉, Pb(Zr,Ti)O₃ and Bi₄Ti₃O₁₂.

7. The method according to claim 1, which comprises forming the metal-oxide containing layer as a dielectric layer including a paraelectric material.

8. The method according to claim 1, which comprises forming the metal-oxide containing layer as a dielectric layer including a paraelectric barium strontium titanate compound.

9. The method according to claim 1, which comprises forming the metal-oxide containing layer as a dielectric layer including (Ba,Sr)TiO₃ as a paraelectric material.

10. The method according to claim 1, which comprises forming the conductive protective layer from a material selected from the group consisting of a high-temperature superconductor, a nitride, and a carbide.

11. The method according to claim 1, which comprises forming the conductive protective layer from a material selected from the group consisting of WSi, IrOₓ, RhOₓ, RuOₓ, OsOₓ, SrRuO₃, LaSrCoOₓ, YBa₂Cu₃O₇, WN TaN, and WC, where x is a real number.

12. The method according to claim 1, which comprises:
applying, subsequent to the step of forming the contact opening, the conductive protective layer as a first covering
layer substantially entirely covering the semiconductor substrate;
applying a tungsten layer as a second covering layer substantially entirely covering the semiconductor substrate; and
removing material of the conductive protective layer and of the tungsten layer in a region outside the contact opening by chemical mechanical polishing.

13. The method according claim 1, which comprises:
after the step of applying the first insulation layer, forming a first contact hole in the first insulation layer;
providing, via the first contact hole, a first contact between a drain region of the switching transistor and the lower electrode;
after the step of applying the second insulation layer, forming a second contact hole which passes through the first and second insulation layers; and
providing, via the second contact hole, a second contact between a source region of the switching transistor and a further outer contact connection.

14. The method according to claim 1, which comprises:
after the step of applying the second insulation layer, forming a first contact hole which passes through the second insulation layer and the first insulation layer;
providing, via the first contact hole, a first contact between a source region of the switching transistor and an outer connection;
after the step of applying the second insulation layer, forming a second contact hole which passes through the second insulation layer and the first insulation layer;
providing, via the second contact hole, a second contact between the drain region and a further outer connection;
after the step of applying the second insulation layer, forming a third contact hole which passes through the second insulation layer; and
providing, via the third contact hole, a third contact between the upper electrode and the further outer connection.

15. A method for fabricating a semiconductor component, the method which comprises:
forming a switching transistor on a semiconductor substrate;
applying a first insulation layer on the switching transistor;
forming a storage capacitor on the first insulation layer such that the storage capacitor is coupled to the switching transistor, the storage capacitor including a lower electrode, an upper electrode and a metal-oxide-containing layer disposed between the lower electrode and the upper electrode, the lower electrode and the upper electrode containing a material selected from the group consisting of a platinum metal and a conductive oxide of a platinum metal;
applying a conductive protective layer at least in a given region of the upper electrode;
subsequently applying a second insulation layer on the storage capacitor;
forming, at the given region of the upper electrode, a contact opening in the second insulation layer for providing an electrical contact between the upper electrode and an outer contact connection;
after the steps of applying the second insulation layer and forming the contact opening, filling the contact opening with tungsten by using a chemical vapor deposition in a hydrogen atmosphere.

16. The method according to claim 15, which comprises forming the lower electrode and the upper electrode from a material containing platinum.

17. The method according to claim 15, which comprises forming the lower electrode and the upper electrode from platinum.

18. The method according to claim 15, which comprises forming the metal-oxide containing layer as a dielectric layer including a ferroelectric material.

19. The method according to claim 15, which comprises forming the metal-oxide containing layer as a dielectric layer including a ferroelectric material selected from the group consisting of a strontium bismuth tantalate compound, a strontium bismuth tantalate niobate compound, a lead zirconate titanate compound and a barium titanate compound.

20. The method according to claim 15, which comprises forming the metal-oxide containing layer as a dielectric layer including a ferroelectric material selected from the group consisting of SrBi₂(Ta,Nb)₂O₉, Pb(Zr,Ti)O₃ and Bi₄Ti₃O_{12.}

21. The method according to claim 15, which comprises forming the metal-oxide containing layer as a dielectric layer including a paraelectric material.

22. The method according to claim 15, which comprises forming the metal-oxide containing layer as a dielectric layer including a paraelectric barium strontium titanate compound.

23. The method according to claim 15, which comprises forming the metal-oxide containing layer as a dielectric layer including (Ba, Sr) TiO₃ as a paraelectric material.

24. The method according to claim 15, which comprises forming the conductive protective layer from a temperature resistant material which can withstand temperatures of over 650° C. in an O₂ atmosphere.

25. The method according to claim 15, which comprises forming the conductive protective layer from a temperature resistant material which can withstand temperatures of over 650° C. in an O₂ atmosphere and is selected from the group consisting of WSi, IrOₓ, RhOₓ, RuOₓ, OsOₓ, SrRuO₃, LaSrCoOₓ, and a high-temperature superconductor, where x is a real number.

26. The method according to claim 25, which comprises using YBa₂Cu₃O₇ as the high-temperature superconductor.

27. The method according to claim 15, which comprises:
forming the upper electrode by applying an electrode layer substantially entirely over the semiconductor substrate;
subsequently applying the conductive protective layer on the electrode layer such that the protective layer substantially entirely covers the electrode layer; and
patterning the electrode layer and the conductive protective layer by using photolithography and etching.

28. The method according claim 15, which comprises:
after the step of applying the first insulation layer, forming a first contact hole in the first insulation layer;
providing, via the first contact hole, a first contact between a drain region of the switching transistor and the lower electrode;
after the step of applying the second insulation layer, forming a second contact hole which passes through the first and second insulation layers;
providing, via the second contact hole, a second contact between a source region of the switching transistor and a further outer contact connection.

29. The method according to claim 15, which comprises:
after the step of applying the second insulation layer, forming a first contact hole which passes through the second insulation layer and the first insulation layer;
providing, via the first contact hole, a first contact between a source region of the switching transistor and an outer connection;
after the step of applying the second insulation layer, forming a second contact hole which passes through the second insulation layer and the first insulation layer;
providing, via the second contact hole, a second contact between a drain region and a further outer connection;
after the step of applying the second insulation layer, forming a third contact hole which passes through the second insulation layer; and
providing, via the third contact hole, a third contact between the upper electrode and the further outer connection.

30. A semiconductor component, comprising:
a semiconductor substrate;
switching transistor formed on said semiconductor substrate;
a first insulation layer disposed on said switching transistor;
a storage capacitor formed on said first insulation layer, said storage capacitor being coupled to said switching transistor and including a lower electrode, an upper electrode and a metal-oxide-containing layer disposed between said lower electrode and said upper electrode;
said lower and upper electrodes of said storage capacitor containing a material selected from the group consisting of a platinum metal and a conductive platinum metal oxide;
a second insulation layer disposed on said storage capacitor;
said second insulation layer being formed with a contact opening and tungsten filling said contact opening;
a conductive protective layer disposed in said contact opening and at least on said upper electrode; and
an outer contact connection electrically contacting said upper electrode.

31. The semiconductor component according to claim 30, wherein said conductive protective layer in said contact opening is disposed only on said upper electrode.

32. The semiconductor component according to claim 30, wherein:
said second insulation layer defines inner walls for said contact opening; and
said conductive protective layer covers said inner walls.

33. The semiconductor component according to claim 30, wherein said lower and upper electrodes contain platinum.

34. The semiconductor component according to claim 30, wherein said lower and upper electrodes consist of platinum.

35. The semiconductor component according to claim 30, wherein said metal-oxide-containing layer is a dielectric layer including a ferroelectric material.

36. The semiconductor component according to claim 30, wherein said metal-oxide-containing layer is a dielectric layer including a ferroelectric material selected from the group consisting of SrBi₂(Ta,Nb)₂O₉, Pb(Zr,Ti)O₃, and Bi₄Ti₃O₁₂.

37. The semiconductor component according to claim 30, wherein said metal-oxide-containing layer is a dielectric layer including a paraelectric material.

38. The semiconductor component according to claim 30, wherein said metal-oxide-containing layer is a dielectric layer including (Ba, Sr) TiO₃.

39. The semiconductor component according to claim 30, wherein said conductive protective layer is formed of a material selected from the group consisting of a high-temperature superconductor, a nitride, and a carbide.

40. The semiconductor component according to claim 30, wherein said conductive protective layer is formed of a material selected from the group consisting of WSi, IrOₓ, RhOₓ, RuOₓ, OsOₓ, SrRuO₃, LaSrCoOₓ, YBa₂Cu₃O₇, WN, TaN, and WC, where x is a real number.

41. The semiconductor component according to claim 30, wherein:
said first insulation layer is formed with a first contact hole;
said switching transistor has a drain region and a source region;
a first conductive material fills said first contact hole for providing a contact between said drain region and said lower electrode;
said first and second insulation layers are formed with a second contact hole which passes through said first and second insulation layers;
a second conductive material fills said second contact hole; and
a further outer contact connection contacts said source region via said second conductive material.

42. The semiconductor component according to claim 30, wherein:
said first and second insulation layers are formed with a first contact hole which passes through said first and second insulation layers;
said switching transistor has a drain region and a source region;
a first conductive material fills said first contact hole;
a further outer contact connection is contacted to said source region via said first conductive material;
said first and second insulation layers are formed with a second contact hole which passes through said first and second insulation layers;
a second conductive material is disposed in said second contact hole;
another outer contact connection contacts said drain region via said second conductive material;
said second insulation layer is formed with a third contact hole which passes through said second insulation layer; and
a third conductive material is disposed in said third contact hole for providing a contact between said another outer contact connection and said upper electrode.
